(19) United States
(12) Patent Application Publication
(10) Pub. No.: US 2008/0185723 A1
(43) Pub. Date: Aug. 7, 2008

(54) Semiconductor device

(75) Inventor: Yoshikazu Moriwaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/068,309

(22) Filed: Feb. 5, 2008

(30) Foreign Application Priority Data
Feb. 6, 2007 (JP) 2007-026570

(51) Int. Cl. H01L 23/525

(52) U.S. Cl. 257/758; 257/E23.147

(57) ABSTRACT

An antifuse includes a first conductor pattern, a sidewall insulating film formed on a side of the first conductor pattern, and a second conductor pattern formed so that the sidewall insulating film is interposed between the first and second conductor patterns and so as to face the side of the first conductor pattern. The antifuse utilizes the sidewall insulating film as a capacitor insulating film of a capacitor.

This application is based upon and claims the benefit of priority from Japanese patent application No. 2007-026570, filed on Feb. 6, 2007, the disclosure of which is incorporated herein in its entirety by reference.

### TECHNICAL FIELD

The present invention relates to a semiconductor device and, in particular, to an electrically programmable antifuse and a semiconductor device provided with the same.

### BACKGROUND OF THE INVENTION

Higher capacity and higher integration of a semiconductor device is developed every year. For example, in a Dynamic Random Access Memory (DRAM), a high-capacity product having 1 G bits becomes commercial. A redundant circuit is adopted in such a high-capacity semiconductor memory. A defective cell generated due to contamination of a foreign substance during a production process or an inferior cell having a refresh characteristic below the standard due to variation of the production process is replaced with a preliminary substitution cell (namely, redundant cell). Since the inferior cell is replaced with the preliminary substitution cell by utilizing the redundant circuit, a production yield is enhanced. In the redundant circuit, by writing an address of the inferior cell into a fuse to be stored, the replacement to the preliminary substitution cell is carried out.

Further, a semiconductor device generates various reference voltage values by increasing or decreasing a power supply voltage value applied from an external. A reference voltage generating circuit utilizes a fuse in order to finely adjust the reference voltage value. Thus, a number of fuses for storing an address of a redundant circuit or for adjustment of a circuit are utilized in the semiconductor device. There are two main types of fuses including a laser trimmer fuse and an antifuse.

The laser trimmer fuse is a fuse that becomes a non-conduction state from a conduction state by cutting polysilicon wiring or metal wiring by the use of a laser trimmer apparatus. Since such wiring is cut by laser beam, throughput is lowered and such a manner cannot be used after packaging. Therefore, the laser trimmer fuse is utilized for saving of a circuit in a wafer state or for adjustment. The antifuse is constructed from a capacitor including a capacitor insulating film disposed between a pair of electrodes. When a high voltage value that is equal to or higher than a critical voltage value is applied to the pair of electrodes of the capacitor, the insulating film of the capacitor becomes breakdown to cause a short circuit. In this manner, the antifuse becomes a conduction state from a non-conduction state. Since writing into the antifuse is electrically carried out, the writing can be carried out after packaging. Therefore, the antifuse is often adopted.

An existing antifuse is structured by one transistor that includes a gate electrode, source and drain electrodes and a substrate electrode, which are formed on a silicon substrate. A gate insulating film serves as an insulating film of the capacitor. Such an antifuse is formed by processes that are the same as those of a general transistor for a circuit. While the substrate electrode of the transistor is set to ground potential, voltage of a high electrical field is applied to the gate electrode. In this manner, breakdown of the gate insulating film of the transistor occurs. The breakdown of the gate insulating film results in ohmic connection between the gate electrode and the substrate so as to serve as the antifuse.

In general, when a film thickness of the gate insulating film of the transistor becomes thin, a breakdown phenomenon in the gate insulating film becomes soft breakdown. When hard breakdown occurs in the insulating film, a large current of a few orders flows as a gate leak current due to the breakdown of the gate insulating film. The break portion forms ohmic connection. On the other hand, when soft breakdown occurs in the insulating film, the break portion does not form excellent ohmic connection. Therefore, an increase of the gate leak current value by only one breakdown may be less than twofold.

When the thickness of the gate insulating film becomes thin, the soft breakdown occupies in the breakdown phenomenon. Thus, after the breakdown of the gate insulating film occurs, the antifuse not having an ohmic characteristic may be generated. In order that the antifuse surely has an ohmic characteristic after the breakdown of the gate insulating film occurs, a thickness of the insulating film is required to be equal to or thicker than a gate insulating film thickness (Tox>3 nm) that has a hard breakdown characteristic. Thus, a gate insulating film having a thick thickness is to be used in order to form the antifuse that can operate stably.

On the other hand, the gate insulating film of the transistor mounted on a semiconductor device tends to become thin due to scaling of the semiconductor device. Thus, it is required to introduce a thick gate insulating film for an antifuse in order to form the antifuse having a stable breakdown characteristic. A process such as a multi-oxide process different from processes for the general transistor for circuit operation is required to be introduced for thickening the gate insulating film for the antifuse. This causes a problem that the number of processes is increased. Further, an existing antifuse has the same structure as that of a general transistor for circuit operation, and an area of the conventional antifuse is not so small in the same manner as that of the general transistor. Therefore, a chip occupied area problematically becomes larger if a number of antifuses are mounted on a chip.

A schematic view of an antifuse according to a related technology is shown in FIG. 1.

The antifuse has the same structure as that of the general transistor for circuit operation, and comprises devise isolation insulating films 2, an N⁺ gate electrode 3, N⁺ SD diffusion layers (including N⁻ LDD) 4, P⁺ SUB diffusion layers and a gate insulating film 6, which are formed on a silicon substrate (SUB)1. Herein, both the N⁺ SD diffusion layers 4 serve as a source (S) and a drain (D), respectively while the P⁺ SUB diffusion layer 5 serves as an electrical potential supplying diffusion layer for the silicon substrate (SUB) 1.

The N⁺ gate electrode 3 has a multilayer structure including a doped polysilicon layer and a metal layer and the like.

Both the N⁺ SD diffusion layers 4 and the P⁺ SUB diffusion layers 5 are commonly connected to an electrical potential Vs. The N⁺ gate electrode 3 of the transistor is connected to electrical potential Vg. In the case where the electrical potential Vg is set larger than 0 M and the electrical potential Vs is set smaller than 0 M, bias of a high electrical field is applied to the gate insulating film 6. In this manner, the breakdown of the gate insulating film 6 occurs. The N⁺ gate electrode 3 is ohmically connected with the P⁺ SUB diffusion layers 5 so as to serve as the antifuse.

There are Patent Documents that disclose a semiconductor device on which an antifuse is mounted as follows. U.S. Pat. No. 4,899,205 (Patent Document 1) discloses an antifuse in which a capacitor is provided between a diffusion layer and an electrode by forming a plurality of insulating films and electrodes on the diffusion layer. Japanese Patent No. 2,783,398 (Patent Document 2) discloses an antifuse in which an insulating film and an electrode are formed on a drain diffusion layer as a PROM array comprising an access transistor and an antifuse. Japanese Patent Application Publication No. 2003-168734 (Patent Document 3) discloses an antifuse formed from an insulating film that has a thickness thinner than that of a gate insulating film of a transistor for a circuit. Japanese Patent No. 3,275,893 (Patent Document 4) discloses an antifuse including a gate electrode and a combination of source and drain electrodes and a substrate, which are opposed electrodes.

Each of the above Patent Documents discloses the antifuse utilizing a surface of a semiconductor substrate or a diffusion layer as one electrode, and utilizing a gate insulating film or a plurality of insulating films. However, each of the Patent Documents fails to suggest problems of the present invention and a technical concept or idea for solving the problems.

### SUMMARY OF THE INVENTION

A semiconductor device uses an antifuse utilizing a gate insulating film of a transistor. On the other hand, the gate insulating film of the transistor tends to become thinner in accordance with scaling of the semiconductor device. In the case where the insulation film becomes thinner, there is a problem that an ohmic characteristic between the gate electrode and a substrate cannot be obtained due to occurrence of soft breakdown. Moreover, since such an antifuse has the same structure as that of the transistor, there is a problem that a size of the antifuse becomes larger.

In view of the above problems, it is an object of the present invention to provide an antifuse indicating an ohmic characteristic in breakdown of an insulating film and having a small size, and a semiconductor device provided with the same.

In order to solve the above-mentioned problems, the present application basically adopts techniques described below. Further, it goes without saying that various modifiable and changeable applied technologies are also included without departing from the technical scope of the present invention.

In one aspect of the present invention, a semiconductor device of the present invention includes an antifuse, wherein the antifuse comprises a first conductor pattern, a sidewall insulating film formed on a side of the first conductor pattern and a second conductor pattern formed so that the sidewall insulating film is interposed between the first and second conductor patterns and so as to face the side of the first conductor pattern.

In the semiconductor device of the present invention, it is preferable that the antifuse is formed within a devise isolation insulating region.

In the semiconductor device of the present invention, it is preferable that the first conductor pattern is a gate electrode pattern and the second conductor pattern is a contact electrode pattern.

In the semiconductor device of the present invention, it is preferable that the sidewall insulating film is a gate sidewall nitride film.

In the semiconductor device of the present invention, it is preferable that the sidewall insulating film has a film thickness so that hard breakdown occurs at insulation breakdown.

In the semiconductor device of the present invention, it is preferable that the sidewall insulating film has a film thickness of an equivalent oxide thickness thicker than a film thickness of a gate insulating film of a transistor that is used as an internal circuit.

In another aspect of the present invention, an antifuse of the present invention comprises a first conductor pattern, a sidewall insulation film formed on a side of the first conductor pattern and a second conductor pattern formed so that the sidewall insulation film is interposed between the first and second conductor patterns and so as to face the side of the first conductor pattern.

In the antifuse of the present invention, it is preferable that the first and second conductor patterns and the sidewall insulation film are formed within a devise isolation insulating region.

In the antifuse of the present invention, it is preferable that the first conductor pattern is a gate electrode pattern, the second conductor pattern is a contact electrode pattern, and the sidewall insulation film is a gate sidewall nitride film.

In the antifuse of the present invention, it is preferable that the sidewall insulation film has a thickness thicker than a film thickness of a gate insulation film of a transistor that is used as an internal circuit and so that hard breakdown occurs at insulation breakdown.

The antifuse of the present invention utilizes the sidewall insulating film as a capacitor insulating film. Even in the case where the gate insulating film of the transistor becomes thinner, a thickness of the capacitor insulating film of the antifuse can be controlled independently of a thickness of the gate insulating film. Therefore, there is no need for an additional process that specializes in the capacitor insulating film of the antifuse, such as a multi-oxide process. By utilizing a thick gate sidewall insulating film, breakdown of the insulating film becomes hard breakdown. In this manner, the antifuse having an excellent ohmic characteristic can be obtained. Moreover, the antifuse is formed in an electrically floating state relative to the substrate within the device isolation insulating region, and is structured by the gate electrode and the contact electrode of the general transistor for circuit operation. Thus, the antifuse can be formed in a smaller space than that of the transistor. Therefore, a small-sized antifuse can be obtained.

### BRIEF DESCRIPTION OF THE DRAWINGS

FIG. 1 is a schematic view of an antifuse according to a related technology; and

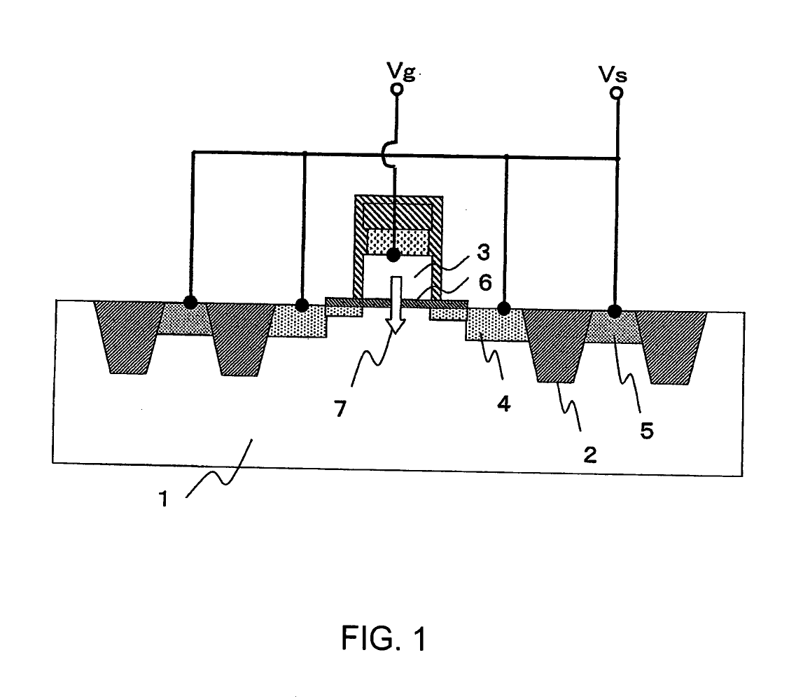

FIG. 2 is a schematic view of an antifuse according to the present invention.

### DESCRIPTION OF THE EXEMPLARY EMBODIMENTS

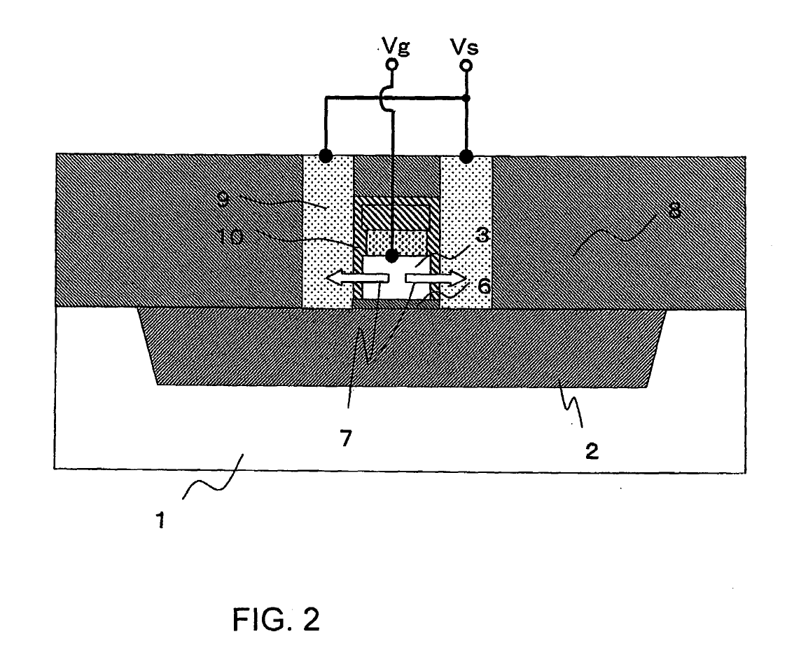

An antifuse of the present invention will be described with reference to FIG. 2. A schematic view of an antifuse according to the present invention is shown in FIG. 2.

A devise isolation insulating film 2 is formed on a silicon substrate 1 and a transistor that will become an antifuse is formed on the device isolation insulating film 2. A circuit transistor is formed within an active region. The transistor for the antifuse is formed within the device isolation insulating region at the same time as the process of forming the circuit transistor. A gate insulating film 6 and an N⁺ gate electrode 3 are formed. Then, a gate sidewall nitride film 10 is formed as a sidewall insulating film of the N⁺ gate electrode 3 of the transistor. A thickness of the gate sidewall nitride film 10 is set to a thickness for preventing soft breakdown from occurring. The N⁺ gate electrode 3 may be replaced with a P⁺ gate electrode in accordance with a process for applying the antifuse of the present invention thereto.

After a gate interlayer insulating film 8 is formed, contact electrodes 9 are formed by a self align contact (SAC) process. In a general transistor, the contact electrodes 9 are connected to source and drain diffusion layers, respectively. However, in the case of a transistor for the antifuse, this contact electrode 9 is caused not to conduct to the silicon substrate 1, and serves as one of a pair of electrodes for a capacitor. The transistor for the antifuse is formed within the device isolation region 2, and the N⁺ gate electrode 3 and the contact electrodes 9 are required to be formed in a state where they are electrically floated on the silicon substrate 1 in both horizontal and depth directions with respect to FIG. 2.

Before the gate interlayer insulating film 8 is formed, a film such as a nitride film may be formed as an etching stopper upon forming the contact electrodes 9. Formation of such an etching stopper film does not affect a function of the antifuse. As described above, the gate sidewall insulating film (the gate sidewall nitride film 10) serves as a capacitor insulating film of the antifuse while the gate electrode 3 and the contact electrodes 9 serve as a pair of electrodes for the capacitor. Although the contact electrodes 9 are formed on both sides in FIG. 2, the contact electrode 9 may be formed on only one side of the gate electrode 3.

By forming the antifuse within the device isolation insulating region in this manner, the antifuse can be formed at the same time as the formation of the general transistor at the same process. Thus, there is no need to provide a specific process for forming the antifuse. However, the processes for forming the antifuse are not limited to the same processes for forming the general transistor. A part of the processes may be applied to a special process for forming the antifuse in order to obtain a more stable antifuse. For example, although the gate sidewall nitride film 10 is used as the sidewall insulating film, a special sidewall insulating film for the antifuse may be used.

As described above, the capacitor is formed so that the N⁺ gate electrode 3 of the transistor serves as one of the pair of electrodes, the gate sidewall nitride film 10 serves as the capacitor insulating film, and the contact electrode 9 serves as another of the pair of electrodes. An antifuse of the prior art is an antifuse in which a lower electrode, a capacitor insulating film and an upper electrode are perpendicularly laminated in this order on a surface of a silicon substrate. On the other hand, the antifuse of the present invention comprises the N⁺ gate electrode 3, the gate sidewall nitride film 10 at a side position of the N⁺ gate electrode 3, and the contact electrode 9 at a side position of the gate sidewall nitride film 10. Thus, the antifuse of the present invention is an antifuse in which such elements are laterally laminated. An equivalent oxide thickness (EOT) of a thickness of the device isolation in a depth direction is required to be set sufficiently thicker than a thickness of the gate sidewall nitride film 10. For example, a gate sidewall EOT film thickness is 5 nm in the case where a device isolation ETO film thickness is 200 nm.

In the antifuse having the structure shown in FIG. 2, writing is carried out by applying high voltage having a voltage value that is equal to or higher than a critical voltage value to the capacitor insulating film. When bias voltage of Vg [V] (Vg>0) is applied to the N⁺ gate electrode 3 of the transistor and bias voltage of Vs [V] (Vs<0) is applied to each of the contact electrodes 9, insulation breakdown of the gate sidewall nitride film 10 occurs. The insulation breakdown of the capacitor insulating film occurs so that the N⁺ gate electrode 3 is ohmically connected to the contact electrodes 9. In this manner, the antifuse can be obtained. A current at this state flows in a horizontal direction in FIG. 2 (arrows 7) and between the N⁺ gate electrode 3 and each of the contact electrodes 9. Since the capacitor insulating film of the antifuse serves as the thick gate sidewall insulating film, hard breakdown occurs. Thus, an excellent ohmic characteristic can be obtained.

In the present invention, in place of the gate insulating film of the transistor, the gate sidewall insulating film 10 of the transistor is utilized as the capacitor insulating film of the antifuse. The antifuse is an antifuse in which the gate electrode 3, the gate sidewall insulating film 10 and the contact electrode 9 are laterally laminated and arranged. The high bias voltage of Vg [V] (Vg>0) is applied to the gate electrode 3 of the transistor that is formed in an electrically floating state relative to the silicon substrate 1 on the device isolation insulating film 2, and the high bias voltage of Vs [V] (Vs<0) is applied to the contact electrode 9 of the transistor. Application of the high bias results in insulation breakdown of the gate sidewall insulation film 10 that is interposed between the gate electrode 3 and the contact electrode 9 that is formed by a self align contact (SAC) process.

The breakdown of the thick gate sidewall insulating film 10 enables ormic conduction between the gate electrode 3 and the contact electrode 9 of the transistor. Further, since the antifuse is structured by the gate electrode 3 and the contact electrode 9 that is formed by the SAC process, an antifuse that has a size smaller than that of the circuit transistor can be obtained by the same processes as the general processes.

Although the present invention has been described in conjunction with a preferred embodiment thereof, the present invention is not limited to the embodiment described above. Various modifications and changes can be applied to the present invention without departing from the scope of the present invention. It goes without saying that such modifications and changes are to be included in the present invention.

What is claimed is:

1. A semiconductor device having an antifuse, wherein the antifuse comprises:
a first conductor pattern;
a sidewall insulating film formed on a side of the first conductor pattern; and
a second conductor pattern formed so that the sidewall insulating film is interposed between the first and second conductor patterns and so as to face the side of the first conductor pattern.

2. The semiconductor device as claimed in claim 1, wherein the antifuse is formed within a device isolation insulating region.

3. The semiconductor device as claimed in claim 2, wherein the first conductor pattern is a gate electrode pattern and the second conductor pattern is a contact electrode pattern.

4. The semiconductor device as claimed in claim 3, wherein the sidewall insulating film is a gate sidewall nitride film.

5. The semiconductor device as claimed in claim 4, wherein the sidewall insulating film has a film thickness so that hard breakdown occurs at insulation breakdown.

6. The semiconductor device as claimed in claim 4, wherein the sidewall insulating film has a film thickness of an equivalent oxide thickness thicker than a film thickness of a gate insulating film of a transistor that is used as an internal circuit.

7. An antifuse, comprising:
a first conductor pattern;
a sidewall insulating film formed on a side of the first conductor pattern; and
a second conductor pattern formed so that the sidewall insulating film is interposed between the first and second conductor patterns and so as to face the side of the first conductor pattern.

8. The antifuse as claimed in claim 7, wherein the first and second conductor patterns and the sidewall insulating film are formed within a device isolation insulating region.

9. The antifuse as claimed in claim 8, wherein the first conductor pattern is a gate electrode pattern, the second conductor pattern is a contact electrode pattern, and the sidewall insulating film is a gate sidewall nitride film.

10. The antifuse as claimed in claim 9, wherein the sidewall insulating film has a thickness thicker than a film thickness of a gate insulating film of a transistor that is used as an internal circuit so that hard breakdown occurs at insulation breakdown.
